(19) United States
(12) Patent Application Publication
(10) Pub. No.: US 2025/0291261 A1
(43) Pub. Date: Sep. 18, 2025

(54) METHOD AND SYSTEM FOR ADJUSTING MASK DEFORMATION

(71) Applicant: LIDS SEMICONDUCTOR TECHNOLOGY CO., LTD., Taichung City (TW)

(72) Inventors: Chun-Jung Chiu, Taichung City (TW); Chun-Hsiung Chen, Taichung City (TW); Wen-Tung Yang, Taichung City (TW)

(21) Appl. No.: 19/078,494

(22) Filed: Mar. 13, 2025

(30) Foreign Application Priority Data
Mar. 15, 2024 (TW) 113109806

(51) Int. Cl. G03F 7/00; G01B 11/25; G03F 1/84; G06T 7/00

(52) U.S. Cl. CPC G03F 7/70725; G01B 11/25; G03F 1/84; G03F 7/70775; G06T 7/001; G06T 2207/30148

(57) ABSTRACT

A method and system for adjusting mask deformation are provided to enhance the accuracy of lithography processes, which are critical to semiconductor manufacturing. The method involves projecting structured light onto a mask to capture a reference image before the mask makes contact with a wafer. If this reference image, referred to as the first image, is not already stored, the system captures it by projecting structured light onto the surface of the mask. A wafer is then placed on a support platform (the wafer stage) that is moved underneath the mask. The upward movement of the support platform brings the wafer into contact with the mask, forming a convex pattern that indicates mask deformation, referred to as the second image. A computing device analyzes the difference between the first and second images to guide adjustments of the support platform, ensuring that mask deformation remains within a predetermined range.

### TECHNICAL FIELD

The present invention relates to a detection and adjustment method, and more particularly to a method and system for adjusting the deformation of a mask in semiconductor lithography processes.

### BACKGROUND

Photolithography is a critical step in semiconductor device fabrication. In this process, geometric patterns are formed on a photoresist layer through exposure and development, and these patterns on the mask are then transferred onto the substrate or wafer through etching.

In photolithography, one method is contact lithography, in which the wafer is moved until it comes into contact with the mask before exposure is carried out to form the pattern on the wafer. Please refer to FIGS. 1A and 1B. FIGS. 1A and 1B are schematic views of contact lithography. As shown in FIG. 1A, a mask 14 is arranged on a holder 13, and a wafer 12 is positioned below the mask 14 on a support platform (carrier) 11. Then, referring to FIG. 1B, the support platform 11 is moved upward so that the wafer 12 contacts the lower surface of the mask 14, allowing exposure to be performed on the top surface 14a of the mask 14.

Ideally, the wafer 12 and the mask 14 make full planar contact. However, in practice, errors often occur when moving the support platform 11. As shown in FIGS. 1C and 1D, these errors can cause mask deformation. In FIG. 1C, the support platform 11 fails to maintain perfect levelness as it moves upward, resulting in one side of the wafer 12 pushing too forcefully against the mask 14 and deforming it, while the other side of the wafer 12 fails to contact the mask 14. In FIG. 1D, the support platform 14 (presumably the platform holding the mask 14, or a typo meaning the platform 11) elevates excessively, causing the wafer 12 to press fully into the mask 14 and deform it. Once the mask 14 is deformed or if part of the wafer 12 does not make contact with the mask 14, distortion may occur during exposure, resulting in unexpected patterns on the wafer.

In older processes where the minimum feature size exceeded 5 micrometers, errors caused by the motion of the support platform 11 were still within an acceptable tolerance, so adjusting the platform height was often unnecessary. However, today's processes demand far greater precision, particularly for feature sizes below 2 micrometers. The yield losses caused by platform-induced errors become unacceptable under these higher precision requirements.

Currently, height adjustments of the support platform 11 are typically done manually and rely heavily on experience, which can be unreliable. How to solve the aforementioned problems is thus an area that those skilled in the art would value and seek to improve.

### SUMMARY

In view of the above problems, the present invention provides a method and system for adjusting the deformation of a mask. Through refined detection, quantification, and correction of mask deformation, this invention addresses a major challenge in semiconductor manufacturing.

In the method for adjusting mask deformation according to the present invention, one step involves projecting structured light onto the surface of a mask to establish a deformation-measurement reference. This step includes checking whether there is a previously stored image-referred to as the first image-representing the structured light pattern formed on the mask before contact with the wafer. If this image is not stored, the system proceeds to project structured light onto the mask and capture this crucial reference image.

Subsequently, a wafer is placed on a support platform, which then moves beneath the mask. The platform is elevated so that the wafer comes into contact with the mask. Under structured light illumination, a convex pattern indicating mask deformation is formed at the contact interface.

To assess the extent of this deformation, the system captures a second image depicting the convex pattern formed after contact, allowing direct comparison with the first (reference) image. A computing device analyzes the difference between these two images, effectively quantifying the deformation. Based on this analysis, the computing device adjusts the support platform to ensure that the mask's deformation remains within a predetermined acceptable range. Such adjustment is crucial for accurate pattern transfer during lithography and ultimately contributes to manufacturing high-quality semiconductor devices.

In one embodiment, the structured light comprises fringe patterns, which may be generated in various ways, such as by projecting light through a grating or by using a spatial light modulator.

The system for adjusting mask deformation according to the present invention includes:
(1) a structured light source capable of generating the required light pattern;
(2) an image-capturing device for recording how these structured light patterns appear on the mask; and
(3) a computing device to analyze the captured images and control the support platform.

Through structured light projection, image capture, and computational analysis, the present invention significantly enhances the precision and reliability of photolithography, further advancing the field of semiconductor device fabrication.

### BRIEF DESCRIPTION OF THE DRAWINGS

The objects, spirits, and advantages of the preferred embodiments of the present disclosure will be readily understood by the accompanying drawings and detailed descriptions, wherein:

FIGS. 1A and 1B are schematic views of contact lithography.

FIGS. 1C and 1D are schematic views showing mask deformation caused by contact errors in contact lithography.

FIG. 2 is a flowchart illustrating the method of detecting and adjusting deformation of the mask 14 according to the present invention.

FIG. 3A is a schematic view showing the arrangement of a structured light source and a mask.

FIG. 3B is a schematic view of a first embodiment of a mask deformation detection system 100.

FIG. 3C is a schematic view of a second embodiment of a mask deformation detection system 200.

FIG. 4A is a schematic view of the mask 14 prior to deformation.

FIG. 4B is a schematic view of the mask 14 after deformation.

### DETAILED DESCRIPTION

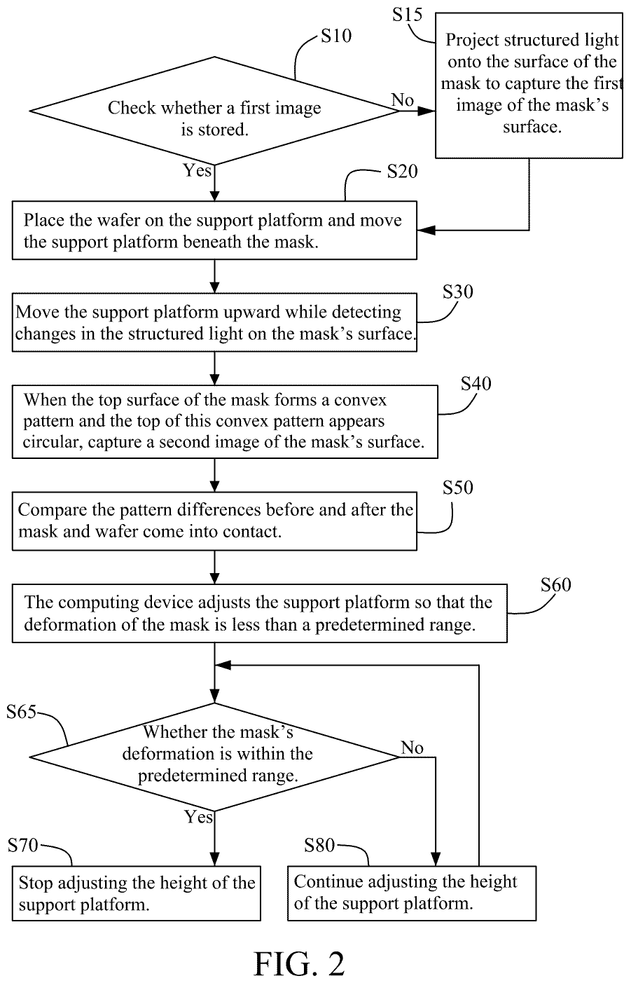

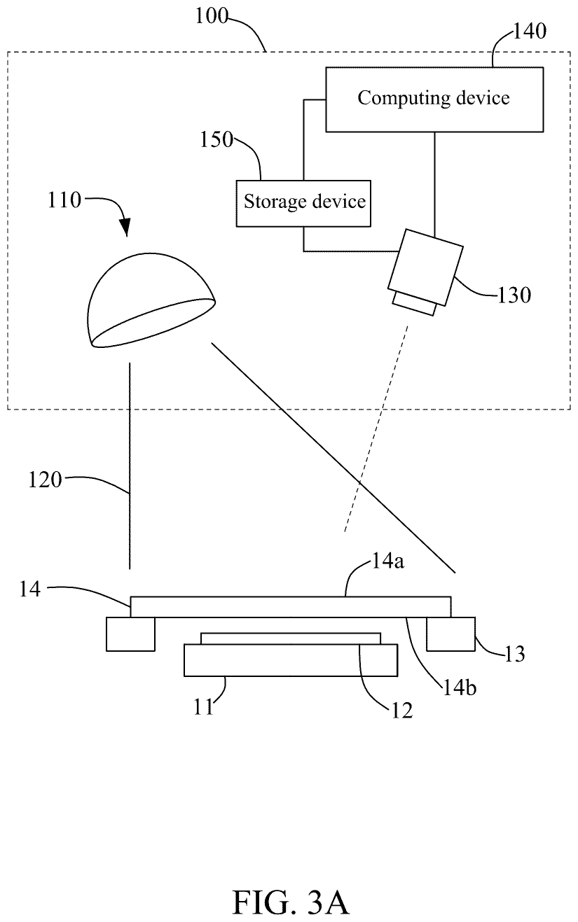

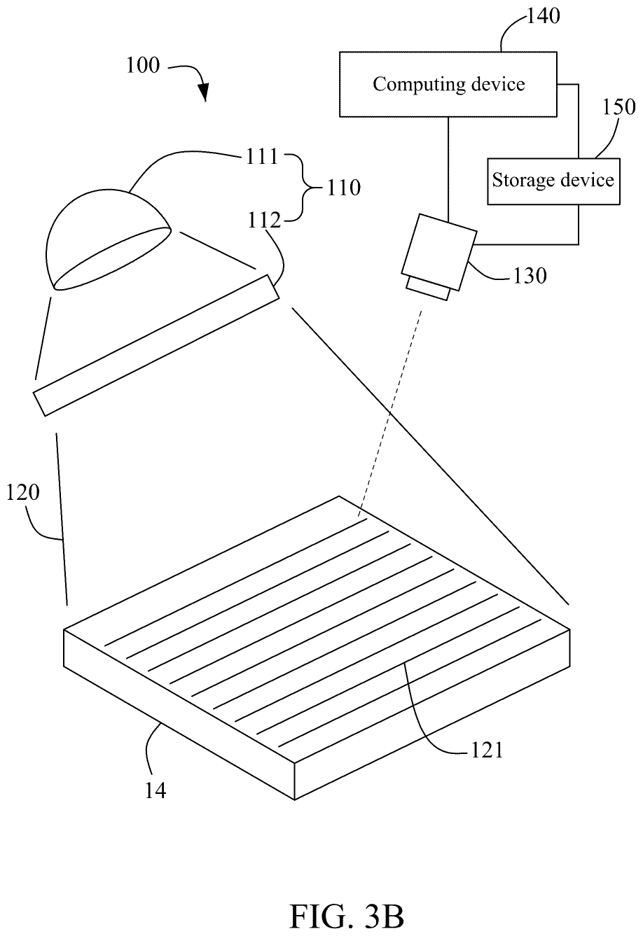

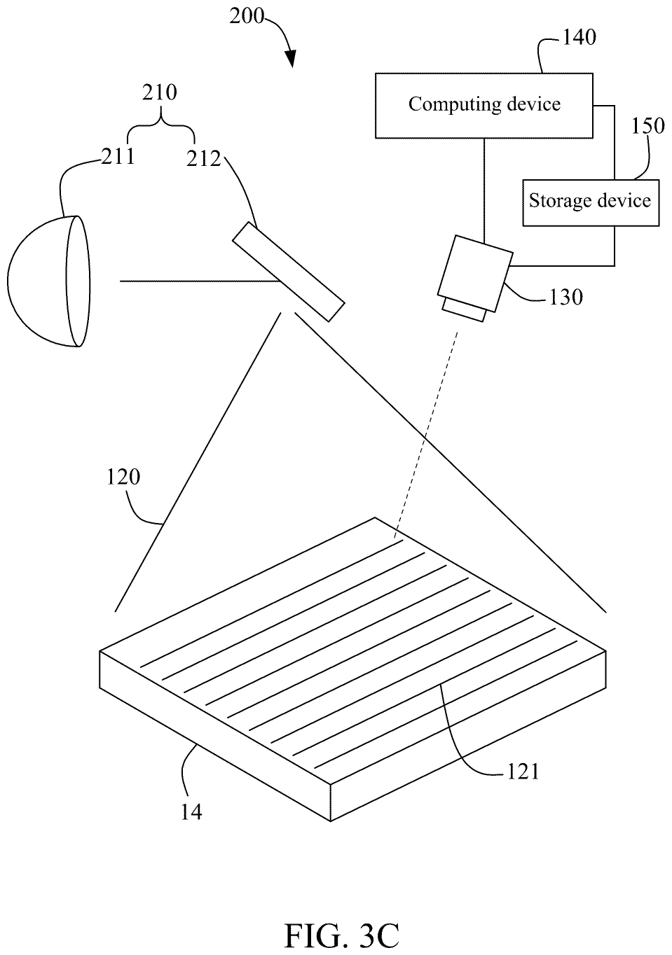

Please refer to FIG. 2, FIG. 3A, and FIG. 3B. FIG. 2 illustrates the method of adjusting mask deformation according to the present invention, FIG. 3A shows the arrangement of a structured light source and a mask, and FIG. 3B depicts a first embodiment of the mask deformation detection system.

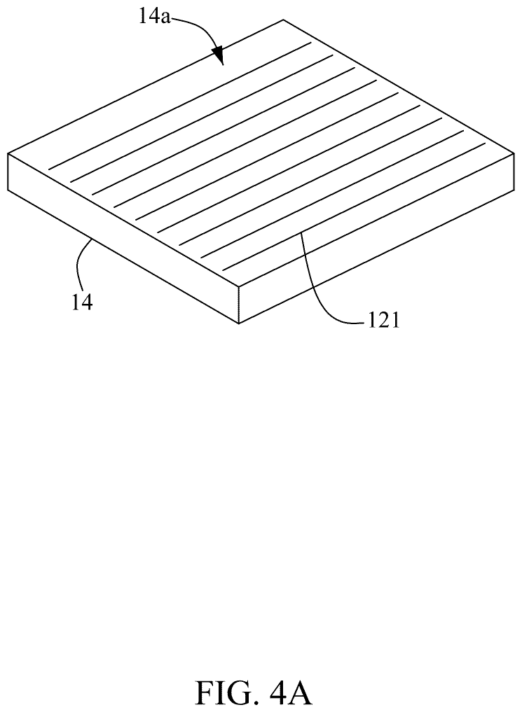

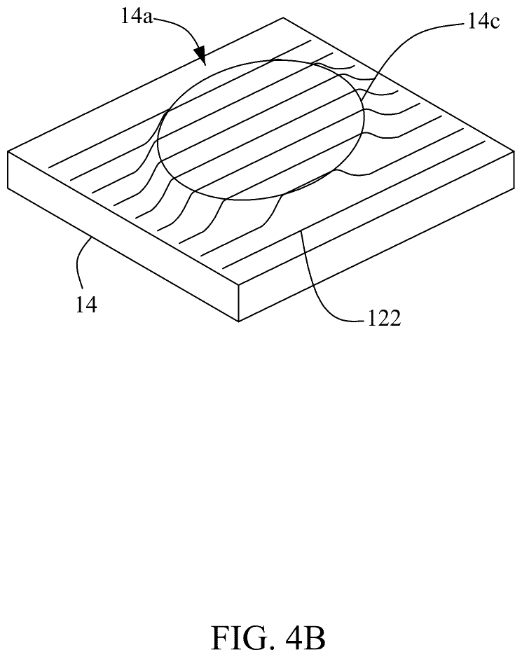

In this embodiment, the mask deformation detection system 100 includes a structured light source 110, an image-capturing device 130, a computing device 140, and a storage device 150. First, in step S10, it is determined whether the storage device 150 already stores an image of structured light illumination on the surface of the mask 14 (relative to the wafer 12) prior to their contact. This image is referred to as the “first image” 121 (see FIG. 4A). If there is no such stored image, step S15 is performed: the structured light source 110 projects structured light 120 onto the surface of the mask 14, and the pattern formed thereby is captured and saved in the storage device 150 as the first image 121. If the image is already stored, the process proceeds to the subsequent steps, i.e., step S20.

In this embodiment, the structured light 120 is a fringe pattern, forming multiple stripes (the pattern 121) on the top surface 14a of the mask 14, as shown in FIGS. 3B, 3C, and 4A. However, the invention is not limited to striped patterns; the structured light pattern could be grid-like, dotted arrays, or coded patterns, and it could be in black-and-white, grayscale, or color.

Referring to FIG. 3B, in the first embodiment, the structured light source 110 includes a light source 111 and a grating 112. The structured light 120 is produced by passing light through the grating 112, forming a corresponding pattern (the first image 121) on the surface of the mask 14. As shown in FIG. 3C, in the second embodiment, the structured light source 210 includes a light source 211 and a spatial light modulator 212. Light emitted from the light source 211 is modulated by the spatial light modulator 212 to form the structured light 120. The spatial light modulator 212 may be a digital micromirror device (DMD) or a liquid crystal on silicon (LCoS) device. It can form structured light 120 through transmissive or reflective modulation, generating the corresponding first image 121 on the mask 14.

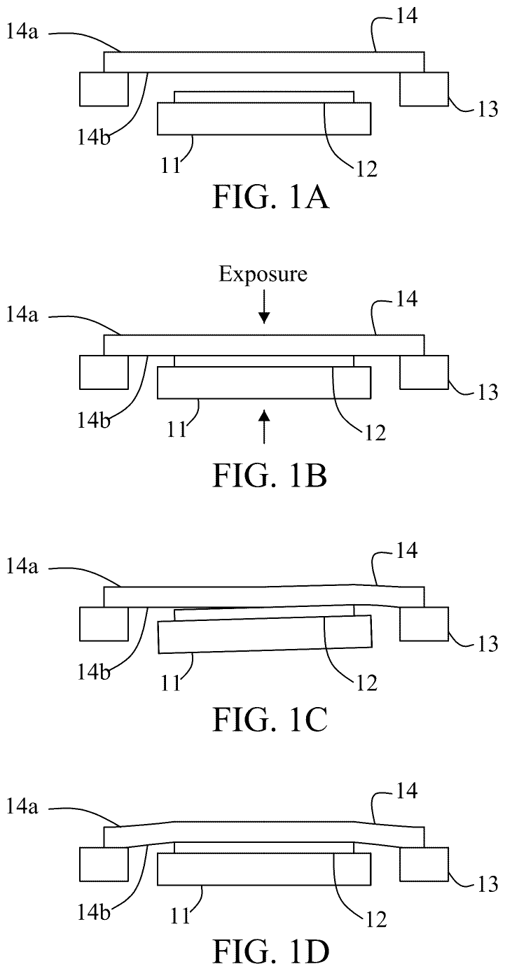

Next, referring again to FIG. 2, in step S20, the wafer 12 is placed on the support platform (carrier) 11, which is then moved beneath the mask 14. This configuration is equivalent to that shown in FIG. 1A. The mask 14 is arranged on a separate mask support platform 13.

In step S30, the support platform 11 is moved upward so that the wafer 12 contacts the mask 14. That is, step S30 is for bringing the surface of wafer 12 intended for exposure into contact with the mask 14, corresponding to the state shown in FIG. 1B, 1C, or 1D. During this step, the image-capturing device 130 continuously monitors the top surface 14a of the mask 14 for signs of deformation. In this embodiment, the image-capturing device 130 can capture images of the mask surface 14a at short time intervals. Alternatively, the computing device 140 may estimate the time required for the wafer 12 to contact the mask 14—based on the distance between the wafer 12 and the mask 14 and the speed at which the support platform 11 moves—and trigger the image-capturing device 130 after this estimated time. If it turns out the wafer 12 has still not contacted the mask 14, a fine adjustment can be initiated until the top surface 14a of the mask 14 is confirmed to deform slightly upon contact.

In step S40, when the top surface 14a of the mask 14 is observed to exhibit a convex pattern 14b (see FIG. 4B), the image formed by the structured light 120 on the mask 14 is captured and stored as a “second image” 122.

In step S50, the computing device 140 compares the first image 121 and the second image 122. In other words, it examines the difference in the patterned appearance before and after the wafer 12 contacts the mask 14 to assess the extent of mask deformation.

Then, in step S60, based on the computed deformation of the mask 14, the computing device 140 controls and adjusts the support platform 11 so that the mask 14's deformation is kept below a predetermined range.

In step S65, the computing device 140 determines whether the mask 14's deformation is within an acceptable range (i.e., less than or equal to the predetermined range). If so, the computing device 140 stops adjusting the height of the support platform 11 (as shown in step S70). Otherwise, the system continues adjusting the height of the support platform 11 until the computing device 140 confirms that the mask 14's deformation is within the acceptable range (step S80). Afterward, subsequent lithography processes may proceed.

In one embodiment, during steps S50 and S60, the computing device 140 uses known information about the wafer 12 (such as size) and the extent of mask 14 deformation to adjust the support platform 11. More specifically, the storage device 150 may store parameters such as the dimensions, materials, and mechanical properties of the wafer 12 and the mask 14. By comparing the first image 121 and the second image 122, the computing device 140 can deduce whether and to what degree the wafer 12 is misaligned (e.g., tilted) and calculate how to adjust the support platform 11 so that the mask 14 deformation is minimized below the predetermined range.

Furthermore, the support platform 11 is moved in the vertical direction by at least three linear actuators controlled by the computing device 140. In steps S60 and S80, the computing device 140 independently adjusts each of these actuators to control the platform's height profile, ensuring that the mask 14's deformation meets the requirement.

Through the above steps (S10 to S80), the system can effectively determine and adjust the contact between the wafer 12 and the mask 14, feeding back control signals to the support platform 11 to ensure good contact and thereby improve the accuracy of subsequent exposures.

Although the present disclosure has been disclosed and illustrated with reference to particular embodiments, the principles involved are susceptible for use in numerous other embodiments that will be apparent to a person having ordinary skill in the art. This disclosure is, therefore, to be limited only as indicated by the scope of the appended claims.

What is claimed is:

1. A method for adjusting deformation of a mask, comprising:
(a) checking whether a first image is stored, wherein the first image is formed by projecting structured light onto a surface of the mask before the mask makes contact with a wafer; if not stored, then projecting the structured light onto the surface of the mask and capturing the resulting pattern as the first image;
(b) placing the wafer on a support platform and moving the support platform beneath the mask;
(c) moving the support platform upward so that the wafer contacts the mask, causing the mask to form a convex pattern on the surface where the structured light is projected, and capturing an image of the structured light on the mask's surface as a second image;
(d) using a computing device to compare a difference between the first image and the second image; and
(e) adjusting the support platform with the computing device based on the difference between the first image and the second image so that the deformation of the mask is below a predetermined range.

2. The method for adjusting mask deformation as claimed in claim 1, wherein the structured light is fringe light.

3. The method for adjusting mask deformation as claimed in claim 2, wherein the structured light is generated by irradiating a light source onto a grating.

4. The method for adjusting mask deformation as claimed in claim 2, wherein the structured light is generated by irradiating a light source onto a spatial light modulator, and then being modulated thereby.

5. The method for adjusting mask deformation as claimed in claim 1, wherein the structured light is generated by irradiating a light source onto a grating.

6. The method for adjusting mask deformation as claimed in claim 1, wherein the structured light is generated by irradiating a light source onto a spatial light modulator, and then being modulated thereby.

7. A system for adjusting mask deformation for detecting whether a mask is deformed, comprising:
a structured light source, suitable for producing structured light and projecting said light onto a surface of the mask;
an image-capturing device, suitable for capturing images of the structured light projected onto the surface of the mask; and
a computing device electrically connected to the image-capturing device;
wherein the image-capturing device is configured to:
store, as a first image, the structured light pattern on the surface of the mask before the mask makes contact with a wafer;
store, as a second image, the structured light pattern on the surface of the mask after the mask contacts the wafer and forms a convex pattern;
wherein the wafer is placed on a support platform;
and wherein the computing device adjusts the height of the support platform based on a difference between the first image and the second image, so that deformation of the mask is maintained below a predetermined range.

8. The system for adjusting mask deformation as claimed in claim 7, wherein the structured light source includes a light source and a grating, and the structured light is generated by projecting the light source through the grating.

9. The system for adjusting mask deformation as claimed in claim 8, wherein the structured light is fringe light.

10. The system for adjusting mask deformation as claimed in claim 7, wherein the structured light is fringe light.

11. The system for adjusting mask deformation as claimed in claim 7, wherein the structured light source comprises a light source and a spatial light modulator, and the structured light is generated by irradiating the spatial light modulator and being modulated thereby.
